(19) United States
(12) Patent Application Publication
(10) Pub. No.: US 2024/0178807 A1
(43) Pub. Date: May 30, 2024

(54) METHODS AND APPARATUS TO REDUCE OFFSET AND GAIN ERROR IN MULTISTAGE CURRENT SENSE AMPLIFIERS

(71) Applicant: Texas Instruments Incorporated, Dallas, TX (US)

(72) Inventors: Ankit Khanna, Tucson, AZ (US); Dimitar Trifonov, Vail, AZ (US); Partha S. Basu, Oro Valley, AZ (US); Chase Puglisi, Tucson, AZ (US)

(21) Appl. No.: 18/070,215

(22) Filed: Nov. 28, 2022

(51) Int. Cl. H03F 3/45; H03F 1/08

(52) U.S. Cl. CPC H03F 3/45475; H03F 1/086; H03F 2200/261; H03F 2200/462; H03F 2203/45134

(57) ABSTRACT

An example apparatus includes: a transconductance stage including: a fully differential amplifier configured to generate a differential current based on a voltage input; and a transistor configured to be controlled by an output of the fully differential amplifier and source current from an input of the fully differential amplifier; and a transimpedance stage coupled to the transconductance stage, the transimpedance stage including: resistor circuitry configured to convert the differential current into a differential voltage using a first resistance, a second resistance, and a third resistance; and a differential amplifier configured to convert the differential voltage to a single-ended voltage, which represents the voltage input.

### TECHNICAL FIELD

This description relates generally to amplifiers, and more particularly to methods and apparatus to reduce offset and gain error in multistage current sense amplifiers.

### BACKGROUND

In-line current sensing is commonly achieved by determining a voltage difference across a resistor in circuitry where a current measurement is to be determined. Additional circuitry, such as controller circuitry, divides the voltage difference across the resistor by the resistance of the resistor to determine the current flowing through the resistor. Typically, in-line current sensing includes a relatively small resistor and an instrumentation amplifier. The instrumentation amplifier is a difference amplifier which includes relatively large input resistances to decrease input current. In the example of in-line current sensing, the instrumentation amplifier is coupled to the relatively small resistor by a first reference input and a second reference input. The instrumentation amplifier converts a voltage difference between the reference input from a differential voltage to a single-ended voltage in reference to a common potential (e.g., ground). For example, an output of the instrumentation amplifier is five millivolts (mV) when the first reference input is sixty and five thousandths' volts (V), and the second reference input is sixty volts (V) when the gain of the instrumentation amplifier is one. In such an example, controller circuitry determines a current through the relatively small resistor is five amps (A) when a resistance of the relatively small resistance is one milliohm (mΩ), and ohms law is applied to solve for current.

### SUMMARY

For methods and apparatus to reduce offset and gain error in multistage current sense amplifiers, an example apparatus includes a transconductance stage made with a fully differential amplifier configured to generate a differential current based on a differential voltage input; and transistor's configured to be controlled by the output of the fully differential amplifier and source current from an input of the fully differential amplifier; and a transimpedance stage coupled to the transconductance stage, the transimpedance stage including: resistor circuitry configured to convert the differential current into a single ended voltage the single-ended voltage represents the voltage output.

### BRIEF DESCRIPTION OF THE DRAWINGS

FIG. 1 is a schematic diagram of an example motor driver system configured to supply power to an example motor based on a current measurement determined by example controller circuitry using an example instrumentation amplifier.

FIG. 2 is a schematic diagram of an example implementation of the instrumentation amplifier of FIG. 1 including an example transconductance stage and an example transimpedance stage, the transimpedance stage further including variable resistors configured to reduce offset and gain errors.

FIG. 3 is a block diagram of an example implementation of the controller circuitry of FIG. 1 configured to trim the voltage output of FIG. 2 by determining and setting resistances of the variable resistors of FIG. 2.

FIG. 4 is a flowchart representative of an example method that may be performed using machine readable instructions that can be executed and/or hardware configured to implement the controller circuitry of FIGS. 1 and 3 to reduce offset and gain errors of the instrumentation amplifier of FIGS. 1 and 2.

FIG. 5 is a flowchart representative of an example method that may be performed using machine readable instructions that can be executed and/or hardware configured to implement the controller circuitry of FIGS. 1 and 3 to reduce negative gain error in the instrumentation amplifier of FIGS. 1 and 2.

FIGS. 6A and 6B (collectively, FIG. 6) is a flowchart representative of an example method that may be performed using machine readable instructions that can be executed and/or hardware configured to implement the controller circuitry of FIGS. 1 and 3 to reduce positive and reference gain errors in the instrumentation amplifier of FIGS. 1 and 2.

The same reference numbers or other reference designators are used in the drawings to designate the same or similar (functionally and/or structurally) features.

### DETAILED DESCRIPTION

The drawings are not necessarily to scale. Generally, the same reference numbers in the drawing(s) and this description refer to the same or like parts. Although the drawings show regions with clean lines and boundaries, some or all of these lines and/or boundaries may be idealized. In reality, the boundaries and/or lines may be unobservable, blended and/or irregular.

Applications which require current measurements may include a resistor at a location where current is to be measured. Such applications measure a voltage difference across the resistor to determine current flowing through the resistor. For example, Ohms law allows circuitry to calculate a current flowing through a resistor by dividing a voltage drop across the resistor by a resistance of the resistor. Such a method of current sensing may be referred to as in-line current sensing. An example implementation of in-line current sensing includes a relatively small resistor and an instrumentation amplifier. The relatively small resistor is placed between two points where current is to be measured. Such a resistor placement is referred to as in-line. The relatively small resistor includes a resistance, which is configured to be relatively small, such as to decrease any potential decrease resulting from the addition of the resistance.

The instrumentation amplifier includes a first reference input and a second reference input coupled across the relatively small resistor. The instrumentation amplifier generates an output voltage approximately equal to a gain times a voltage difference between the first reference input and the second reference input. For example, the output voltage of the instrumentation amplifier is ten volts (V) when the gain is two, the first reference input is twenty volts (V), and the second reference input is fifteen volts (V). Some applications need an instrumentation amplifier capable of bi-directional operation with relatively high bandwidth and precision, e.g., sensing current being supplied to a motor by a switching power supply.

One method of increasing a precision of current sensing using an instrumentation amplifier is to amplify an input voltage by a gain. Typically, such a method needs an instrumentation amplifier that includes resistors configured to create a closed loop gain proportional to resistances of the resistors. However, closed control loops are limited by a product of its gain and bandwidth being constant, such that, as a bandwidth of the instrumentation amplifier decreases as the gain increases. For example, an instrumentation amplifier with a closed loop gain has a response time to variations in the input voltage that increases as the gain increases. Separating the operations of an instrumentation amplifier into two-stages prevents increases in the response time as the gain increases. In two stage instrumentation amplifiers, an overall gain is equal to the product of the gain of the two stages, which allows each stage to include a relatively low closed loop gain. The relatively low closed loop gains result in a relatively high bandwidth at relatively high gains.

Typically, a first stage includes circuitry to reduce the common-mode voltage of the reference inputs. The first stage generates a differential output that is representative of the voltage difference between the reference inputs. One type of first stage implements a closed loop amplifier that is configured to use resistor pairs for voltage feedback. In such a configuration, mismatches in the resistor pairs results in offset and gain errors. Additionally, increases in the common-mode voltage of the reference inputs increases an input current of the first stage. As the input current increases, mismatches between the resistors used to amplify the voltage input increase offset and gain errors. A voltage feedback first stage may include trim circuitry for each resistor comprising the resistor pairs and trim circuitry for the output of the amplifier. Such trim circuitry reduces offset resulting from changes in the common mode. However, such trim circuitry increases the area and needs a symmetrical placement in a system on chip (SoC) design.

Typically, a second stage includes a differential-to-single-ended conversion which converts the differential voltage from the first stage into a single-ended voltage representing the voltage difference between the reference inputs. One method of implementing the second stage is to use an amplifier coupled to the output of the first stage.

The examples described herein include an instrumentation amplifier configured to include trim circuitry coupled to variable resistors configured to be set to resistances that reduce offset and gain errors. In some described examples, the instrumentation amplifier includes a first stage and a second stage that support bi-directional current sensing, such as both negative and positive voltage differences. The first stage is a transconductance stage that converts a voltage difference between two reference inputs into a differential current. The first stage includes circuitry to support differential current feedback, which allows bi-directional current sensing and a bandwidth that is proportional to current being sensed. Advantageously, the differential current, generated by the first stage, isolates the common-mode voltage of the reference inputs from the second stage without using resistor pairs for voltage feedback.

The second stage is a transimpedance stage that converts the differential current of the first stage to a single-ended voltage at a voltage output. The second stage includes input and feedback resistors which are configured to reduce offset and gain errors on the voltage output. The input and feedback resistors include variable resistances whose values may be modified by a trim process in order to increase precision by reducing gain and offset errors.

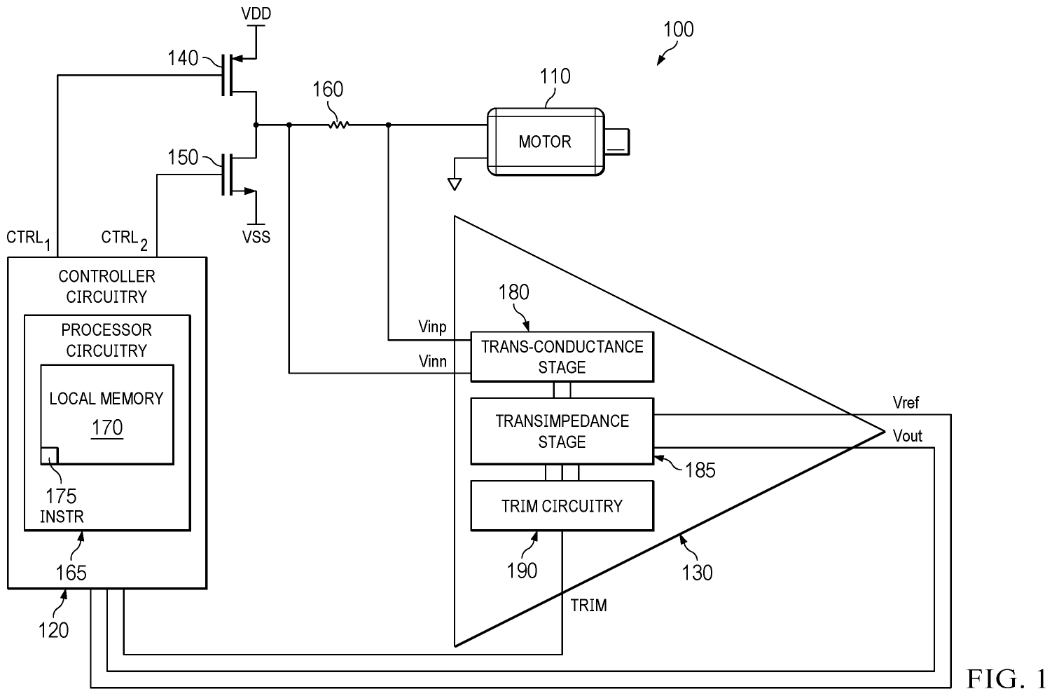

FIG. 1 is a schematic diagram of an example motor driver system 100 configured to supply power to an example motor 110 based on a current measurement determined by example controller circuitry 120 using an example instrumentation amplifier 130. In the example of FIG. 1, the motor driver system 100 includes the motor 110, the controller circuitry 120, the instrumentation amplifier 130, a first example transistor 140, a second example transistor 150, and an example resistor 160. The motor driver system 100 supplies power to the motor 110 using the controller circuitry 120 to turn on and off the transistors 140 and 150. The controller circuitry 120 calculates power being supplied to the motor 110 based on a single-ended voltage at a voltage output (Vout) of the instrumentation amplifier 130. The voltage output of the instrumentation amplifier 130 represents a voltage difference across the resistor 160. The controller circuitry 120 applies Ohm's law to determine current being supplied as the voltage difference across the resistor 160 divided by R_{S}, which is the resistance of the resistor 160.

In the example of FIG. 1, the controller circuitry 120 is coupled to the instrumentation amplifier 130 and the transistors 140 and 150. The controller circuitry 120 controls the first transistor 140 by a first control signal at a first control output (CTRL₁). The controller circuitry 120 controls the second transistor 150 by a second control signal at a second control output (CTRL₂). The controller circuitry 120 controls power supplied to the motor 110 by modifying the first and second control outputs. For example, to increase power supplied to the motor 110, the controller circuitry 120 may modify a duty cycle of a pulse width modulation signal being generated as the first control output. The controller circuitry 120 may determine to modify power supplied to the motor 110 based on the voltage output of the instrumentation amplifier 130. For example, the controller circuitry 120 may use Ohm's law to determine the current supplied to the motor 110 is less than a target value. In such an example, the controller circuitry 120 increases power being supplied to the motor 110 to supply power equal to the target value to the motor 110.

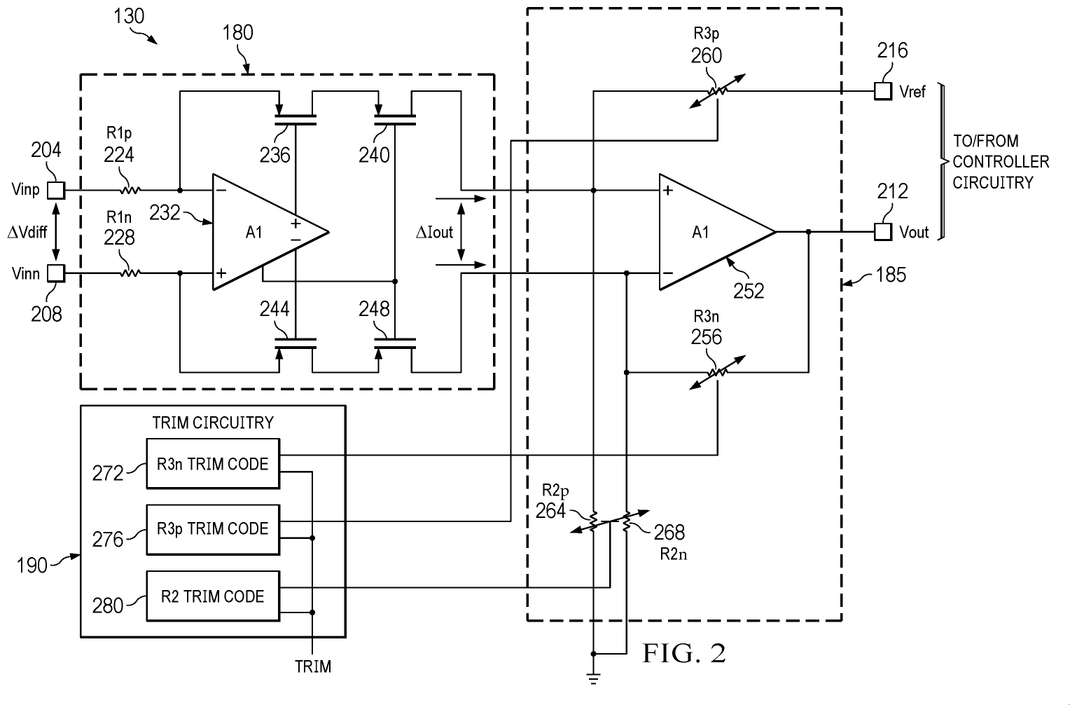

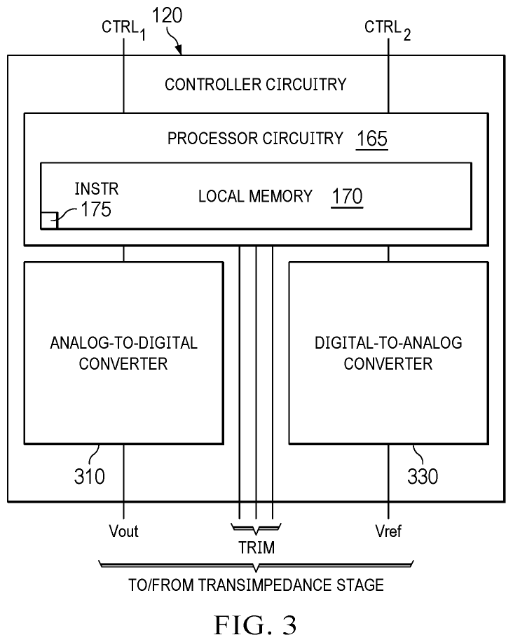

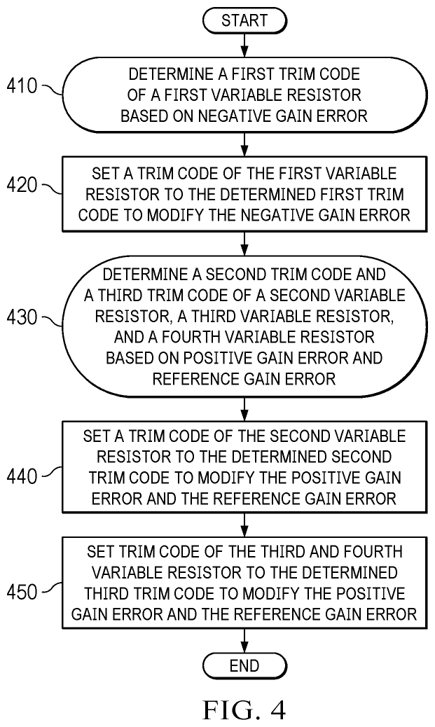

The controller circuitry 120 reduces gain errors of the instrumentation amplifier 130 by setting trim inputs (TRIM) of the instrumentation amplifier 130. The trim inputs modify variable resistors whose resistances are determined by the trim input. The variable resistors of the instrumentation amplifier 130 are illustrated in connection with FIG. 2, below. The controller circuitry 120 is configured to implement the operations of FIGS. 4-6 to determine trim values that reduce offset and gain errors of the voltage output of the instrumentation amplifier 130. An example implementation of the controller circuitry 120 is illustrated in connection with FIG. 3, below.

The controller circuitry 120 includes example processor circuitry 165. The processor circuitry 165 is configured to execute and/or instantiate the instruction(s) and/or operations to implement operations of the controller circuitry 120. The processor circuitry 165 can be implemented by one or more integrated circuits, logic circuits, FPGAs, microprocessors, CPUs, GPUs, DSPs, and/or microcontrollers from any desired family or manufacturer or can even be integrated in the instrumentation amplifier 120. The processor circuitry 165 may be implemented by one or more semiconductor based (e.g., silicon based) devices. The processor circuitry 165 of the illustrated example includes a local memory 170 (e.g., a cache, registers, etc.). The local memory 170 includes example instruction(s) 175. The instruction(s) 175 are representative of machine executable operations to implement the controller circuitry 120. For example, the instruction(s) 175 may include operations representative of the operations of FIGS. 4-6, below.

The instrumentation amplifier 130 is coupled to the motor 110, the controller circuitry 120, the first transistor 140, the second transistor 150, and the resistor 160. In the example of FIG. 1, the instrumentation amplifier 130 includes an example transconductance stage 180, an example transimpedance stage 185, and example trim circuitry 190. The instrumentation amplifier 130 converts a voltage difference across the resistor 160 to a voltage output (Vout). An example implementation of the instrumentation amplifier 130 is illustrated and discussed in further detail in connection with FIG. 2, below.

The transconductance stage 180 is coupled across the resistor 160, which may be more than one resistor. The transconductance stage 180 is coupled to the transimpedance stage 185. The transconductance stage 180 converts the voltage difference across the resistor 160 to a differential current using a current feedback loop (illustrated and discussed in connection with FIG. 2, below). Advantageously, the current feedback loop of the transconductance stage 180 creates a bandwidth that is proportional to the transconductance of transistors implemented in the current feedback. The bandwidth created by the current feedback loop of the transconductance stage 180 is further discussed in connection with FIG. 2, below. The transconductance stage 180 supplies the differential current to the transimpedance stage 185.

The transimpedance stage 185 is coupled to controller circuitry 120, the transconductance stage 180, and the trim circuitry 190. The transimpedance stage 185 converts the differential current from the transconductance stage 180 into a single-ended voltage at the voltage output. The transimpedance stage 185 includes variable resistors (illustrated in FIG. 2, below) that are configured to resistances based on the trim circuitry 190. The transimpedance stage 185 uses the resistances of the variable resistors to amplify the output voltage by a gain, reduce gain errors, and reduce offset errors.

The trim circuitry 190 is coupled to the controller circuitry 120 and the transimpedance stage 185. The trim circuitry 190 stores trim codes based on the trim input from the controller circuitry 120. The trim circuitry 190 may modify the resistances of the variable resistors by modifying trim codes of the variable resistors. The controller circuitry 120 may modify resistances of the transimpedance stage 185 by modifying the trim codes of the trim circuitry 190. For example, the controller circuitry 120 may change the amplification of the voltage output from a gain of two to four by modifying the trim codes of the trim circuitry 190.

The first transistor 140 is coupled to the controller circuitry 120, the second transistor 150, the resistor 160, and a first reference potential (VDD). The first transistor 140 allows current to flow from the first reference potential towards the second transistor 150 and/or the resistor 160 when turned on (e.g., conducting) by the controller circuitry 120. The first transistor 140 prevents current from flowing from the first reference potential towards the second transistor 150 and/or the resistor 160 when turned off (e.g., not conducting) by the controller circuitry 120. The first transistor 140 is a P-channel metal oxide semiconductor field effect transistor (MOSFET). Alternatively, the first transistor 140 may be a PNP bipolar junction transistor (BJT), an N-channel field-effect transistor (FET), an N-channel insulated-gate bipolar transistor (IGBT), an N-channel junction field effect transistor (JFET), a P-channel MOSFET, a P-channel FET, a P-channel IGBT, a P-channel JFET, or an NPN BJT.

The second transistor 150 is coupled to the controller circuitry 120, the first transistor 140, the resistor 160, and a second reference potential (VSS). The second transistor 150 allows current to flow from the first transistor 140 and/or the resistor 160 towards the second reference potential when turned on (e.g., conducting) by the controller circuitry 120. The second transistor 150 prevents current from flowing from the first transistor 140 and/or the resistor 160 when turned off (e.g., not conducting) by the controller circuitry 120. The second transistor 150 is an N-channel MOSFET. Alternatively, the second transistor 150 may be a PNP BJT, an N-channel FET, an N-channel IGBT, an N-channel JFET, a P-channel MOSFET, a P-channel FET, a P-channel IGBT, a P-channel JFET, or an NPN BJT.

The resistor 160 is coupled to the motor 110, the instrumentation amplifier 130, the first transistor 140, and the second transistor 150. Current flowing through the resistor 160 may be determined by applying ohms law, such as to divide the voltage difference across the resistor 160 by its resistance R_{S}.

FIG. 2 is a schematic diagram of an example implementation of the instrumentation amplifier 130 of FIG. 1 including the transconductance stage 180 of FIG. 1, the transimpedance stage 185 of FIG. 1, and the trim circuitry 190 of FIG. 1. The transconductance stage 180 converts a voltage difference between a first reference input 204 and a second reference input 208 into a differential current at a differential current output (ΔIout). The transconductance stage 180 supplies the differential current to the transimpedance stage 185. The transimpedance stage 185 converts the differential current to a single-ended voltage at a voltage output (Vout) 212 based on a reference voltage input (V_{ref}) 216 and trim codes from the trim circuitry 190.

In the example of FIG. 2, the transconductance stage 180 includes a first example resistor 224, a second example resistor 228, an example fully differential amplifier 232, a first example transistor 236, a second example transistor 240, a third example transistor 244, and a fourth example transistor 248. The transconductance stage 180 uses current feedback between outputs of the fully differential amplifier 232 and the transistors 236 and 244 to generate the differential current based on the potential difference between the reference inputs 204 and 208. The transistors 240 and 248 allow a relatively large voltage difference between source inputs and drain outputs, which isolates a common-mode voltage of the reference inputs 204 and 208 from the common-mode voltage of the transimpedance stage 185. Although source inputs, source outputs, drain inputs, and/or drain outputs, which may be referred to as current terminals, may be referred to in connection with FIG. 2, the transistors 236-248 may be modified and/or altered in accordance with the teachings disclosed herein.

The first resistor 224 is coupled to the first reference input 204, the fully differential amplifier 232, and the first transistor 236. The first resistor 224 includes a first resistance (Rip). The first resistor 224 uses the first reference input 204 to supply current to the first transistor 236. The first resistor 224 creates a voltage difference approximately equal to the first resistance times the current flowing through the first transistor 236. The first resistor 224 supplies a voltage to the fully differential amplifier 232 equal to a voltage of the first reference input 204 minus the voltage difference generated by supplying current to the first transistor 236.

The second resistor 228 is coupled to the second reference input 208, the fully differential amplifier 232, and the third transistor 244. The second resistor 228 includes a second resistance (R₁ₙ) approximately equal to the first resistance. The second resistor 228 uses the second reference input 208 to supply current to the third transistor 244. The second resistor 228 supplies a voltage to the fully differential amplifier 232 equal to a voltage of the second reference input 208 minus a voltage difference generated by supplying current to the third transistor 244.

The fully differential amplifier 232 is coupled to the first resistor 224 and the first transistor 236 by an inverting input (−). The inverting input may be referred to as an inverting terminal. The fully differential amplifier 232 is coupled to the second resistor 228 and the third transistor 244 by a non-inverting input (+). The non-inverting input may be referred to as a non-inverting terminal. The fully differential amplifier 232 is coupled to the first transistor 236 by a non-inverting output (+). The non-inverting output may be referred to as a non-inverting terminal. The fully differential amplifier 232 is coupled to the transistors 240 and 248 by a reference rail input. The fully differential amplifier 232 is coupled to the third transistor 244 by an inverting output (−). The inverting output may be referred to as an inverting terminal.

The fully differential amplifier 232 controls an amount of current flowing through each of the transistors 236 and 244 based on the inverting and non-inverting inputs. The fully differential amplifier 232 causes the transistors 236 and 244 to individually source a current from the reference inputs 204 and 208 resulting in the resistors 224 and 228 suppling the fully differential amplifier 232 with approximately the same voltage. For example, the fully differential amplifier 232 turns on the first transistor 236 to source a first current and the third transistor 244 to source a second current, which cause potential differences across the resistors 224 and 228 to set the inverting and non-inverting inputs approximately equal to each other. In such an example, the first current and the second current are the differential current being supplied to the transimpedance stage 185. The fully differential amplifier 232 ensures the transistors 240 and 248 are on (e.g., conducting) to allow the transistors 236 and 244 to source currents from the resistors 224 and 228.

The fully differential amplifier 232 may include a bias on the inverting and non-inverting outputs to cause the transistors 236 and 244 to continue to source a bias current when the reference inputs 204 and 208 are approximately equal to each other. The bias current prevents a transconductance (gₘ) of the transistors 236 and 244 from approaching zero. Advantageously, biasing the transistors 236 and 244 prevents relatively low transconductance of the transistors 236 and 244 and relatively low bandwidth of the instrumentation amplifier 130.

The first transistor 236 is coupled to the first resistor 224 and the fully differential amplifier 232 by a source input. The source input may be referred to as a source terminal. The first transistor 236 is coupled to the fully differential amplifier 232 by a control input. The control input may be referred to as a gate input or a control terminal. The first transistor 236 is coupled to the second transistor 240 by a drain output. The drain output may be referred to as a drain terminal. The first transistor 236 sources current from the first resistor 224. The non-inverting output of the fully differential amplifier 232 controls the first transistor 236. The fully differential amplifier 232 may partially turn on (e.g., conducting) and/or fully turn on the first transistor 236. The first transistor 236 supplies current to the second transistor 240. The first transistor 236 is a P-channel MOSFET. Alternatively, the first transistor 236 may be a PNP BJT, an N-channel FET, an N-channel JFET, a N-channel MOSFET, a P-channel FET, a P-channel JFET, or an NPN BJT.

The second transistor 240 is coupled to the first transistor 236 by a source input. The second transistor 240 is coupled to the fully differential amplifier 232 by a control input. The second transistor 240 is coupled to the transimpedance stage 185 by a drain output. The second transistor 240 sources current from the first transistor 236. The second transistor 240 is configured to be always turned on (e.g., conducting) by the fully differential amplifier 232. The second transistor 240 includes a relatively large impedance on the drain output to allow a voltage difference between the source input and the drain output when turned on (e.g., conducting), while allowing current to flow from the source input to the drain output. Such a transistor may be referred to as a power transistor, a high-voltage transistor, and/or a drain extended transistor. Advantageously, the common-mode voltage of drain output of the first transistor 236 may be different than the common-mode voltage of the drain output of the second transistor 240. The second transistor 240 is a P-channel MOSFET. Alternatively, the second transistor 240 may be a PNP BJT, an N-channel FET, an N-channel IGBT, an N-channel JFET, an N-channel MOSFET, a P-channel FET, a P-channel IGBT, a P-channel JFET, or an NPN BJT.

The third transistor 244 is coupled to the second resistor 228 and the fully differential amplifier 232 by a source input. The third transistor 244 is coupled to the fully differential amplifier 232 by a control input. The third transistor 244 is coupled to the fourth transistor 248 by a drain output. The third transistor 244 sources current from the second resistor 228. The inverting output of the fully differential amplifier 232 controls the third transistor 244 based on a voltage of the non-inverting input of the fully differential amplifier 232. The fully differential amplifier 232 may partially turn on (e.g., conducting) and/or fully turn on the third transistor 244. The third transistor 244 supplies current to the fourth transistor 248. The third transistor 244 is a P-channel MOSFET. Alternatively, the third transistor 244 may be a PNP BJT, an N-channel FET, an N-channel JFET, a N-channel MOSFET, a P-channel FET, a P-channel JFET, or an NPN BJT.

The fourth transistor 248 is coupled to the third transistor 244 by a source input. The fourth transistor 248 is coupled to the fully differential amplifier 232 by a control input. The fourth transistor 248 is coupled to the transimpedance stage 185 by a drain output. The fourth transistor 248 sources current from the third transistor 244. The fourth transistor 248 is configured to be always turned on (e.g., conducting) by the fully differential amplifier 232. The fourth transistor 248 includes a relatively large impedance on the drain output to allow a voltage difference between the source input and the drain output when turned on (e.g., conducting), while allowing current to flow from the source input to the drain output. Such a transistor may be referred to as a power transistor, a high-voltage transistor, and/or a drain extended transistor. Advantageously, the common-mode voltage of drain output of the fourth transistor 248 may be different than the common-mode voltage of the drain output of the fourth transistor 248. The fourth transistor 248 is a P-channel MOSFET. Alternatively, the fourth transistor 248 may be a PNP BJT, an N-channel FET, an N-channel IGBT, an N-channel JFET, an N-channel MOSFET, a P-channel FET, a P-channel IGBT, a P-channel JFET, or an NPN BJT.

In an example operation, the differential current output of the transconductance stage 180 is approximately equal to the voltage difference between the reference inputs 204 and 208 divided by an average resistance of the resistors 224 and 228. For example, the differential current is approximately equal to five milliamps (mA) when the voltage difference between the reference inputs 204 and 208 is approximately five volts (V) and the average resistance of the resistors 224 and 228 is approximately one-thousand ohms (Ω). In such an example, the current flowing through the second transistor 240 is greater than the current flowing through the fourth transistor 248. In another example, the differential currents are approximately equal to negative five milliamps (mA) when the voltage difference between the reference inputs 204 and 208 is approximately negative five volts (V) and the average resistance of the resistors 224 and 228 is approximately one-thousand ohms (Ω). In such an example, the current flowing through the second transistor 240 is less than the current flowing through the fourth transistor 248. Advantageously, the transconductance stage 180 may generate a differential current representing positive and negative voltage differences between the reference inputs 204 and 208. The transconductance stage 180 allows the instrumentation amplifier 130 to be bi-directional as long as the transimpedance stage 185 is capable of representing negative voltages on the voltage output 212.

In example operation, the transistors 236 and 244 source the differential current proportional to the voltage difference of the reference inputs 204 and 208. For example, the differential current of the transistors 236 and 244 increases as the voltage difference between the reference inputs 204 and 208 increases. In such a configuration, a transconductance of the transistors 236 and 244 increases as current being sourced increases. The varying transconductance of the transistors 236 and 244 causes the bandwidth of the instrumentation amplifier 130 to be proportional to current flowing through the transistors 236 and 244. Advantageously, the transconductance and bandwidth of the instrumentation amplifier 130 increases as the differential current flowing through the transistors 236 and 244 increases.

In the example of FIG. 2, the transimpedance stage 185 includes an example amplifier 252, a first example variable resistor 256, a second example variable resistor 260, a third example variable resistor 264, and a fourth example variable resistor 268. The transimpedance stage 185 is coupled to the controller circuitry 120 by the voltage output 212 and the reference voltage input 216. The voltage output 212 may be referred to as a measurement terminal. The reference voltage input 216 may be referred to as a reference terminal. The transimpedance stage 185 is coupled to the transconductance stage 180 and the trim circuitry 190. The transimpedance stage 185 converts the differential current from the transconductance stage 180 to a single-ended voltage at the voltage output 212. The single-ended voltage at the voltage output 212 may be amplified by a gain. The gain of the voltage output 212 is determined based on resistances of the resistors 224 and 228 and variable resistances of example resistor circuitry including the variable resistors 256-268. The trim circuitry 190 sets the resistances of the variable resistors 256-268 using trim codes. Advantageously, resistances of the variable resistors 256-268 may be modified to trim the voltage output 212. Advantageously, the gain of the transimpedance stage 185 may be set by the trim codes of the trim circuitry 190.

The amplifier 252 is coupled to the second transistor 240 and the variable resistors 260 and 264 by a non-inverting input (+). The amplifier 252 is coupled to the fourth transistor 248 and the variable resistors 256 and 268 by an inverting input (−). The amplifier is coupled to the voltage output 212 and the first variable resistor 256 by an amplifier output. The amplifier 252 is configured to modify a voltage of the inverting input by modifying a current being supplied to the first variable resistor 256. For example, the amplifier 252 increases a current output at the amplifier output to increase current supplied to the inverting input by the first variable resistor 256. In such an example, the increase in current output increases the voltage of the inverting input across a voltage divider generated by the variable resistors 256 and 268. The amplifier 252 modifies the current at the amplifier output to modify the voltage of the inverting input to be approximately equal to a voltage of the non-inverting input.

The first variable resistor 256 is coupled to the trim circuitry 190, the voltage output 212, the fourth transistor 248, the amplifier 252, and the fourth variable resistor 268. The trim circuitry 190 configures circuitry (not illustrated for simplicity) of the first variable resistor 256 to set its resistance to a first reference resistance (R₃ₙ) based on a first trim code. The first trim code is a digital value (e.g., an eight-bit value) which corresponds to a specific resistance from a range of potential resistances of the first variable resistor 256. The range of potential resistances of the first variable resistor 256 may be divided by a number of potential digital values that the first trim code can represent to determine which resistance corresponds to which first trim value. For example, the first trim code may set the resistance of the first variable resistor 256 to a value between one hundred ohms (Ω) and ten kilohms (kΩ) based on the first trim code. In the example of FIG. 2, the first trim code is set by the trim circuitry 190. Alternatively, the first trim code of the first variable resistor 256 may be set by a manufacturer, by a designer, by a real-time process, etc.

The second variable resistor 260 is coupled to the trim circuitry 190, the reference voltage input 216, the second transistor 240, the amplifier 252, and the third variable resistor 264. The trim circuitry 190 configures circuitry (not illustrated for simplicity) of the second variable resistor 260 to set its resistance to a second reference resistance (R₃ₚ) based on a second trim code. Similar to how the first trim code represents the range of resistances of the first variable resistor 256, the second trim code represents a range of resistances of the second variable resistor 260, which may be the same as the range of resistances of the first variable resistor 256. In the example of FIG. 2, the second trim code is set by the trim circuitry 190. Alternatively, the second trim code of the second variable resistor 260 may be a set by a manufacturer, by a designer, by a real-time process, etc.

The third variable resistor 264 is coupled to the trim circuitry 190, the second transistor 240, the amplifier 252, the second variable resistor 260, and a common potential (e.g., ground). The trim circuitry 190 configures circuitry (not illustrated for simplicity) of the third variable resistor 264 to set its resistance to a second reference resistance (R₂ₚ) based on a third trim code. Similar to how the first trim code represents the range of resistances of the first variable resistor 256, the third trim code represents a range of resistances of the third variable resistor 264. In the example of FIG. 2, the third trim code is set by the trim circuitry 190. Alternatively, the third trim code of the third variable resistor 264 may be set by a manufacturer, by a designer, by a real-time process, etc.

In the example of FIG. 2, the variable resistors 260 and 264 comprise a voltage divider that may be configured to add a direct current (DC) offset to the voltage output 212 based on the reference voltage input 216 and the resistances of the variable resistors 260 and 264. The controller circuitry 120 may add DC offset to the voltage output 212 by modifying a voltage of the reference voltage input 216 and/or by modifying a ratio of the resistances of the variable resistors 260 and 264. For example, the controller circuitry 120 may set the voltage of the reference voltage input 216 to a voltage approximately equal to half of a voltage range of the amplifier 252 to add a DC offset approximately equal to half of the voltage range of the amplifier 252. In such an example, positive voltage differences between the reference inputs 204 and 208 correspond to voltages greater than the DC offset and negative voltage differences between the reference inputs 204 and 208 correspond to voltages less than the DC offset. Advantageously, applying a DC offset using the reference voltage input 216 and the variable resistors 260 and 264 allows the voltage output 212 to represent both positive and negative voltage differences of the reference inputs 204 and 208 using only voltages greater than the common potential.

The fourth variable resistor 268 is coupled to the trim circuitry 190, the fourth transistor 248, the amplifier 252, the first variable resistor 256, and the common potential. The trim circuitry 190 configures circuitry (not illustrated for simplicity) of the fourth variable resistor 268 to set its resistance to a fourth reference resistance (R₂ₙ) based on the third trim code. In the example of FIG. 2, the third trim code is configured to set the resistance of the variable resistors 264 and 268 approximately, preferably exactly, equal to each other.

The trim circuitry 190 is coupled to the controller circuitry 120 and the transimpedance stage 185. In the example of FIG. 2, the trim circuitry 190 includes a first example register 272, a second example register 276, and a third example register 280. The trim circuitry 190 stores the trim codes which configure the resistances of the variable resistors 256-268. In the example of FIG. 2, the controller circuitry 120 sets the trim codes of the registers 272-280. Alternatively, the trim codes of the registers 272-280 may be a set by a manufacturer, by a designer, by a real-time process, etc.

The first register 272 stores a first trim code (R3n_TRIM_CODE) which configures the first reference resistance of the first variable resistor 256. The second register 276 stores the second trim code (R3p_TRIM_CODE) which configures the second reference resistance of the second variable resistor 260. The third register 280 stores the third trim code (R2_TRIM_CODE) which configures the reference resistances of the variable resistors 264 and 268. The controller circuitry 120 sets and/or modifies the trim codes stored in the registers 272-280. Although in the example of FIG. 2, the trim circuitry 190 is illustrated internal to the instrumentation amplifier 130, the trim codes of the registers 272-280 may be included in the local memory 170.

In an example operation, the instrumentation amplifier 130 includes a positive gain (Gain_{Pos}), a negative gain (Gain_{Neg}), and a reference gain (Gain_{ref}). The gain of the instrumentation amplifier 130 depends on the voltage difference between the reference inputs 204 and 208 and the resistances of the resistors 224, 228, and 256-268. A DC offset of the voltage output 212 depends on the reference voltage input 216 and the resistances of the resistors 224, 228, and 256-268. Advantageously, gain and offset errors of the instrumentation amplifier 130 may be reduced by modifying the resistances of the variable resistors 256-268, such as the methods described in FIGS. 4-6, below.

In the example of FIG. 2, the gain of the instrumentation amplifier 130 includes the positive gain when in a positive mode of operation. The positive mode of operation occurs when a voltage of the first reference input 204 is greater than a voltage of the second reference input 208. For example, the instrumentation amplifier 130 has a gain equal to the positive gain when sensing current flowing from the first transistor 140 of FIG. 1 to the motor 110 of FIG. 1. In the positive mode of operation, the first transistor 236 sources more current than the third transistor 244 to compensate for the voltage of the first reference input 204 being greater than the voltage of the second reference input 208. Initially, the additional current of the first transistor 236 causes the voltage at the non-inverting input of the amplifier 252 to be greater than the voltage at the inverting input of the amplifier 252. The amplifier 252 modifies the amplifier output to supply a current that causes the voltage of the inverting input of the amplifier 252 to be approximately equal to the voltage of the non-inverting input.

The positive gain is equal to a voltage of the voltage output 212 divided by the voltage difference between the reference inputs 204 and 208, when the voltage difference is positive (V_{diff}(+ᵥₑ)). Additionally, the positive gain is equal to the second reference resistance (R₃ₚ) divided by the first resistance times one plus a division of the first reference resistance (R₃ₙ) by the fourth reference resistance (R₂ₙ) divided by one plus a division of the first reference resistance by the third reference resistance (R₂ₚ). The positive gain is determined using Equation (1), below.

$${Gain}_{P o s} = \frac{{V}_{o u t}}{{V}_{diff} ( {+}_{ν e} )} = \frac{{R}_{3 p}}{{R}_{1 p}} * \frac{1 + \frac{{R}_{3 n}}{{R}_{2 n}}}{1 + \frac{{R}_{3 p}}{{R}_{2 p}}} , \qquad Equation ( 1 )$$

In the example of FIG. 2, the gain of the instrumentation amplifier 130 includes the negative gain when in a negative mode of operation. The negative mode of operation occurs when a voltage of the first reference input 204 is less than a voltage of the second reference input 208. For example, the instrumentation amplifier 130 has a gain equal to the negative gain when sensing current flowing to the second transistor 150 of FIG. 1 from the motor 110. In the negative mode of operation, the first transistor 236 sources less current than the third transistor 244 to compensate for the voltage of the first reference input 204 being less than the voltage of the second reference input 208. Initially, the additional current of the third transistor 244 causes the voltage at the inverting input of the amplifier 252 to be greater than the voltage at the non-inverting input of the amplifier 252 when the resistances of the variable resistors 264 and 268 are equal, such as in FIG. 2. The amplifier 252 modifies the amplifier output to sink or reduce a supply of current that causes the voltage of the inverting input of the amplifier 252 to be approximately equal to the voltage of the non-inverting input.

The negative gain is equal to the voltage of the voltage output 212 divided by the voltage difference between the reference inputs 204 and 208, when the voltage difference is negative (V_{diff}(−ᵥₑ)). Additionally, the negative gain is equal to the first reference resistance divided by the second resistance. The negative gain is determined using Equation (2), below.

$${Gain}_{N e g} = \frac{{V}_{o u t}}{{V}_{diff} ( {-}_{ve} )} = \frac{{R}_{3 n}}{{R}_{1 n}} , \qquad Equation ( 2 )$$

The reference gain is an additional gain on the voltage output 212 dependent on the reference voltage input 216. In the example of FIG. 2, the reference gain of the instrumentation amplifier 130 is equal to a voltage of the voltage output 212 divided by a voltage of the reference voltage input 216 (V_{ref}). The reference gain is equal to one plus a division of the first reference resistance (R₃ₙ) by the fourth reference resistance (R₂ₙ) divided by one plus a division of the second reference resistance by the third reference resistance (R₂ₚ). The reference gain is determined using Equation (3), below. Variations of the reference gain from an ideal reference gain of one will cause the voltage output 212 to change by a different amount compared to reference voltage input 216 which results in an offset error.

$${Gain}_{ref} = \frac{{V}_{o u t}}{{V}_{r e f}} = \frac{1 + \frac{{R}_{3 n}}{{R}_{2 n}}}{1 + \frac{{R}_{3 p}}{{R}_{2 p}}} , \qquad Equation ( 3 )$$

In example operation, offset errors resulting from the reference gain may be reduced by setting the reference gain equal to approximately one. Additionally, the positive gain of the instrumentation amplifier 130 is equal to the second reference resistance divided by the first resistance when the reference gain is approximately equal to one. In the example of FIG. 2, the trim codes of the variable resistors 256-268 may be set to values, which result in the reference gain being equal approximately equal to one to reduce offset errors. Advantageously, a method of determining trim codes for the variable resistors 256-268 described below in connection with FIGS. 4-6, below, reduces gain errors and offset errors.

In the example of FIG. 2, the transimpedance stage 185 is implemented using variable resistors instead of fixed value resistors to allow circuitry, such as the trim circuitry 190, to modify the reference resistances of the variable resistors 256-268 to reduce gain errors and offset errors. Gain errors and offset errors result from process variations and/or mismatches of resistances. Advantageously, the instrumentation amplifier 130 reduces errors resulting from process variations as a result of the gains being proportional to resistor ratios, such as in Equations, (1), (2), and (3), above. An example method of reducing gain errors, resulting from resistor mismatch, by modifying the variable resistors 256-268 is described below in connection with FIGS. 4-6, below.

In example operation, a designer, manufacturer, processor, etc. may use Equations (1)-(3) to determine initial resistances for the resistors 224 and 228 and trim codes for the variable resistors 256-268 which configure the positive gain and the negative gain to be equal to target values. During the operations described in FIGS. 4-6, below, the initial resistances of the variable resistors 256-268 may be modified by the controller circuitry 120 to reduce gain errors. Advantageously, the trim circuitry 190 may modify the variable resistors 256-268 to reduce gain errors and/or set the reference gain approximately equal to one.

FIG. 3 is a block diagram of an example implementation of the controller circuitry 120 of FIG. 1 configured to trim the voltage output 212 of FIG. 2 by determining resistances of the variable resistors 256-268 of FIG. 2 to values which reduce gain error resulting from resistor mismatch. In the example of FIG. 3, the controller circuitry 120 includes the processor circuitry 165 of FIG. 1, an example analog-to-digital converter (ADC) 310 and an example digital-to-analog converter (DAC) 330. The controller circuitry 120 implements the operations of FIGS. 4-6 to reduce gain errors by modifying the variable resistors 256-268.

The ADC 310 is coupled to the processor circuitry 165 and the voltage output 212 of FIG. 2. The ADC 310 converts an analog voltage at the voltage output 212 to a digital value representative of the analog voltage. The digital value represents a voltage measurement of the voltage output 212. The ADC 310 supplies the digital value to the processor circuitry 165.

The DAC 330 is coupled to the processor circuitry 165 and the reference voltage input 216 of FIG. 2. The DAC 330 converts a digital value from the processor circuitry 165 into an analog voltage representative of the digital value. The controller circuitry 120 may configured a voltage of the reference voltage input 216 to a specific voltage based on the digital value supplied to the DAC 330. The DAC 330 supplies the analog voltage to the instrumentation amplifier 130 by the reference voltage input 216.

In the example of FIG. 3, the processor circuitry 165 is configured to determine trim codes and set trim codes of the trim circuitry 190. The determined trim codes reduce gain errors and offset errors on the voltage output 212. The processor circuitry 165 implements Equations (1)-(3), above, and Equations (4)-(11), below, to determine the trim codes. Such a process of reducing gain errors by modifying circuitry may be referred to as trimming. The method for determining the trim codes of the trim circuitry 190 which reduces the positive gain errors, the negative gain errors, and the reference gain errors is described in connection with FIGS. 4-6, below.

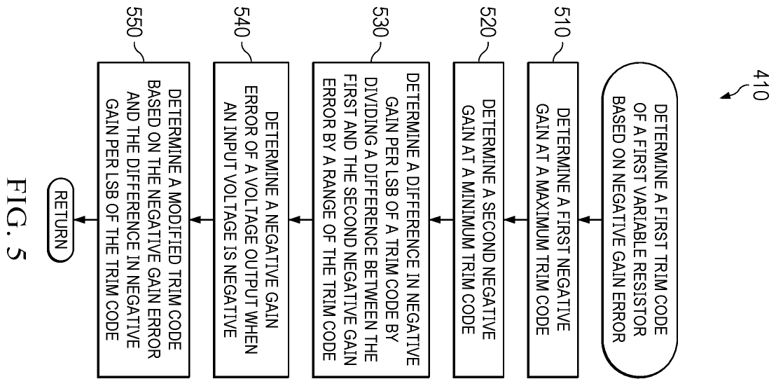

FIG. 4 is a flowchart representative of an example method that may be performed using machine readable instructions that can be executed and/or hardware configured to implement the controller circuitry 120 of FIGS. 1 and 3 to reduce offset and gain errors of the instrumentation amplifier 130 of FIGS. 1 and 2. The method of FIG. 4 begins at block 410. At block 410, the controller circuitry 120 determines a first trim code of the first variable resistor 256 of FIG. 2 based on negative gain error. For example, implementation of FIG. 2, the controller circuitry 120 determines the first trim code (R3n_TRIM_CODE) of the first variable resistor 256 based on a comparison of a change in the negative gain of Equation (2), above, for each increment of the first trim code to the negative gain error. In such an example, the controller circuitry 120 reduces negative gain error by incrementing or decrementing an initial first trim code to correct for the determined negative gain error. The initial trim codes are discussed in connection with FIG. 2, above. The operations of the block 410 are described in further detail in connection with FIG. 5, below. The method of FIG. 4 proceeds to block 420.

At block 420, the controller circuitry 120 sets a trim code of the first variable resistor 256 to the determined first trim code to modify the negative gain error. For example, the controller circuitry 120 sets the first trim code of the first variable resistor 256 to the trim code determined at the block 410 by modifying the first register 272 of FIG. 2. Alternatively, the first trim code may be set in the local memory 170 of FIGS. 1 and 3 and/or configured at a time of manufacture. The process of FIG. 4 proceeds to block 430.

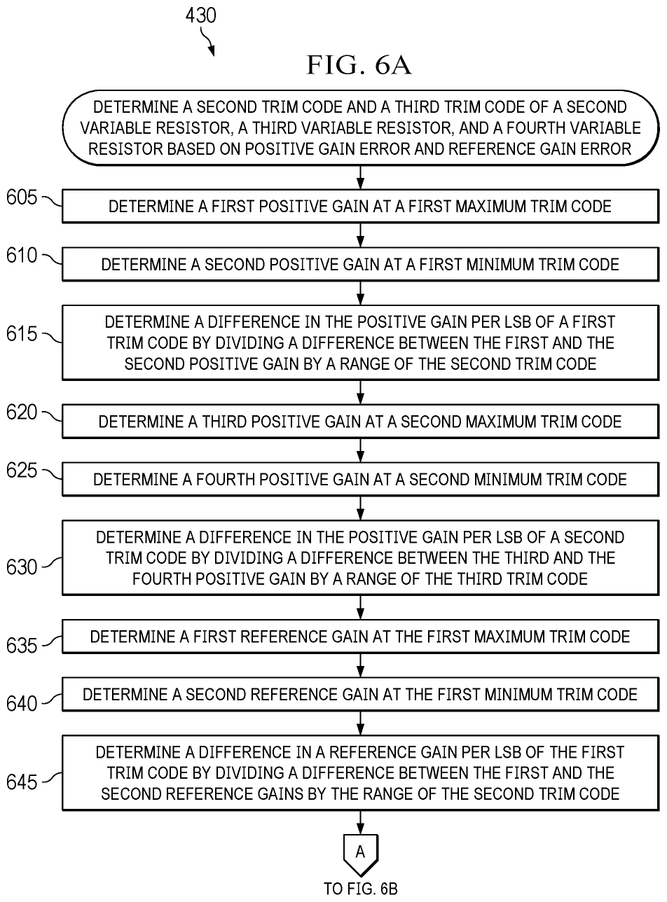

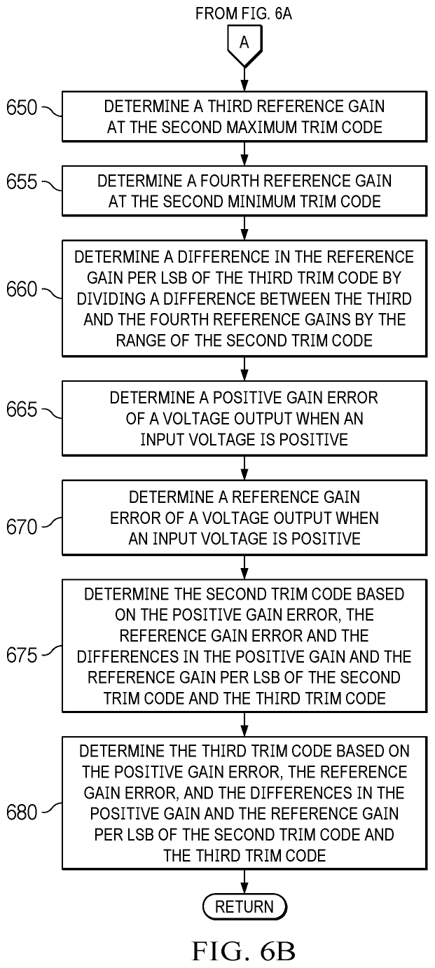

At block 430, the controller circuitry 120 determines a second trim code and a third trim code of the second variable resistor 260 of FIG. 2 and the third variable resistor 264 of FIG. 2 and the fourth variable resistor 268 of FIG. 2 based on positive gain error and reference gain error. For example, the controller circuitry 120 determines the second trim code (R3P_TRIM_CODE) and the third trim code (R2_TRIM_CODE) based on a comparison of modifications to the positive gain of Equation (1), above, and the reference gain of Equation (3), above, per each increment of the second and third trim codes to a measured positive gain error and a measured reference gain error. The block 430 is described in further detail in connection with FIGS. 6A and 6B and Equations (4)-(11), below. The method of FIG. 4 proceeds to block 440.

At block 440, the controller circuitry 120 sets a trim code of the second variable resistor 260 to the determined second trim code to modify the positive gain error and the reference gain error. For example, the controller circuitry 120 sets the second trim code of the second variable resistor 260 to the trim code determined at the block 430 by modifying the second register 276 of FIG. 2. Alternatively, the second trim code may be set in the local memory 170 or configured at a time of manufacture. The process of FIG. 4 proceeds to block 450.

At block 450, the controller circuitry 120 sets a trim code of the variable resistors 264 and 268 to the determined third trim code to modify the positive gain error and the reference gain error. For example, the controller circuitry 120 sets the third trim code of the variable resistors 264 and 268 to the third trim code determined at the block 430 by modifying the third register 280 of FIG. 2. Alternatively, the third trim code may be set in the local memory 170 or configured at a time of manufacture. The process of FIG. 4 proceeds to end.

Although example methods are described with reference to the flowchart illustrated in FIG. 4, many other methods of determining and setting the resistances of the variable resistors 256-268 to reduce gain errors may alternatively be used in accordance with this description. For example, the order of execution of the blocks may be changed, and/or some of the blocks described may be changed, eliminated, or combined. Similarly, additional operations may be included in the manufacturing process before, in between, or after the blocks shown in the illustrated examples.

FIG. 5 is a flowchart representative of an example method that may be performed using machine readable instructions that can be executed and/or hardware configured to implement the controller circuitry 120 of FIGS. 1 and 3 to reduce negative gain error in the instrumentation amplifier 130 of FIGS. 1 and 2. The method of FIG. 5 illustrates an example process of operations performed at the block 410 of FIG. 4. The method of the block 410 begins at block 510. At block 510, the controller circuitry 120 determines a first negative gain when the trim code of the first variable resistor 256 of FIG. 2 is at a maximum trim code (Gain_{neg}(R3nₘₐₓ)), using Equation (2), above. The controller circuitry 120 determines the first negative gain to be equal to a division of the first reference resistance of the first variable resistor 256 at a maximum trim code by the second resistance of the second resistor 228 of FIG. 2. As illustrated in Equation (2), above, when the first reference resistance is equal to a maximum resistance of the first variable resistor 256. The method of FIG. 5 proceeds to block 520.

At block 520, the controller circuitry 120 determines a second negative gain when the trim code of the first variable resistor 256 is at a minimum trim code (Gain_{neg}(R3nₘᵢₙ)) using Equation (2), above. The controller circuitry 120 determines the second negative gain to be a division of the first reference resistance of the first variable resistor at a minimum trim code by the second resistance of the second resistor 228. As illustrated in Equation (2), above, when the first reference resistance is equal to a minimum resistance of the first variable resistor 256. The method of FIG. 5 proceeds to block 530.

At block 530, the controller circuitry 120 determines a difference in negative gain per least significant bit (LSB) of the third trim code (GEvRn) of the first variable resistor 256 based on the first negative gain and the second negative gain. The controller circuitry 120 determines the difference in negative gain per LSB of the first trim code by dividing a subtraction of the second negative gain from the first negative gain by a number of bits between the minimum and maximum trim codes (R3n_{range}). The controller circuitry 120 determines the difference in negative gain per LSB of the third trim code using Equation (4), below. Such a determination results in a value which represents a change in the negative gain per LSB of the first trim code. The method of FIG. 5 proceeds to block 540.

$$GEvRn = \frac{{Gain}_{n e g} ( R 3 {n}_{max} ) - {Gain}_{n e g} ( R 3 {n}_{min} )}{R 3 {n}_{r a n g e}} , \qquad Equation ( 4 )$$

At block 540, the controller circuitry 120 measures the voltage output 212 to determine a negative gain error at a target negative gain (GE_{neg}). The controller circuitry 120 calculates the first reference resistance using Equation (2), above, to configure the negative gain error to the target negative gain. The target negative gain is an ideal gain of the instrumentation amplifier 130 when the voltage difference between the reference inputs 204 and 208 is negative. For example, the controller circuitry 120 determines the first reference resistance should be one kiloohm (kΩ) when the second resistance is equal to three kiloohms (kΩ) and the target negative gain is one-third. In such an example, the controller circuitry 120 determines the negative gain error to be the difference between the target negative gain and a measured negative gain. The controller circuitry 120 determines the measured negative gain is the digital output of the ADC 310 divided by the potential difference between the reference inputs 204 and 208 over two measurement points. The method of FIG. 5 proceeds to block 550.

At block 550, the controller circuitry 120 determines a first trim code based on the negative gain error, determined at block 540, and the difference in the negative gain per LSB of the trim code, determined at block 530. The controller circuitry 120 determines a number of bits to change to the first trim code (Trimcode_{Δ}(R3ₙ)) by dividing the negative gain error by the difference in the negative gain per LSB of the first trim code. The controller circuitry 120 determines the number of bits to change to the first trim code using Equation (5), below. The method of FIG. 5 proceeds to return to the method of FIG. 4.

$${Trimcode}_{Δ} ( {R}_{3 n} ) = \frac{G {E}_{n e g}}{G E v R n} , \qquad Equation ( 5 )$$

Although example methods are described with reference to the flowchart illustrated in FIG. 5, many other methods of determining the resistance of the first variable resistor 256 to reduce negative gain error may alternatively be used in accordance with this description. For example, the order of execution of the blocks may be changed, and/or some of the blocks described may be changed, eliminated, or combined. Similarly, additional operations may be included in the manufacturing process before, in between, or after the blocks shown in the illustrated examples.

FIGS. 6A and 6B are a flowchart representative of an example method that may be performed using machine readable instructions that can be executed and/or hardware configured to implement the controller circuitry 120 of FIG. 1 and to reduce positive and reference gain errors in the instrumentation amplifier 130 of FIGS. 1 and 2. The method of FIGS. 6A and 6B begins at block 605. At block 605, the controller circuitry 120 determines a first positive gain at a first maximum trim code (Gainₚₒₛ(R3pₘₐₓ)) of the second variable resistor 260 of FIG. 2. The second variable resistor 260 sets the second reference resistance to a maximum resistance (R3pₘₐₓ) when the second trim code is equal to the first maximum trim code. The first positive gain of block 605 is determined using the maximum resistance of the second variable resistor 260 in Equation (1), above. The method of FIGS. 6A and 6B proceeds to block 610.

At block 610, the controller circuitry 120 determines a second positive gain at a first minimum trim code (Gainₚₒₛ(R3pₘᵢₙ)) of the second variable resistor 260. The second variable resistor 260 sets the second reference resistance to a minimum resistance (R3pₘᵢₙ) when the second trim code is equal to the first minimum trim code. The second positive gain of block 610 is determined using the minimum resistance of the second variable resistor 260 in Equation (1), above. The method of FIGS. 6A and 6B proceeds to block 615.

At block 615, the controller circuitry 120 determines a difference in the positive gain per LSB of the second trim code (A) by dividing a difference between the first and the second positive gains by a range of the second trim code (R3p_{range}). The controller circuitry 120 determines the difference in the positive gain per LSB of the first trim code of the second variable resistor 260 by dividing the positive gains determined at the blocks 605 and 610 by a number of increments between the first maximum and first minimum trim codes. The determination of the block 615 is illustrated by Equation (6), below. The method of FIGS. 6A and 6B proceeds to block 620.

$$A = \frac{{Gain}_{p o s} ( R 3 {p}_{max} ) - {Gain}_{p o s} ( R 3 {p}_{min} )}{{R 3 p}_{r a n g e}} , \qquad Equation ( 6 )$$

At block 620, the controller circuitry 120 determines a third positive gain at a second maximum trim code (Gainₚₒₛ(R2ₘₐₓ)) of the variable resistors 264 and 268 of FIG. 2. The variable resistors 264 and 268 set the third reference resistance to a maximum resistance (R2ₘₐₓ) when the third trim code is equal to the second maximum trim code. The third positive gain of block 620 is determined using the maximum resistance of the variable resistors 264 and 268 in Equation (1), above. The method of FIGS. 6A and 6B proceeds to block 625.

At block 625, the controller circuitry 120 determines a fourth positive gain at a second minimum trim code (Gainₚₒₛ(R2ₘᵢₙ)) of the variable resistors 264 and 268. The variable resistors 264 and 268 set the third reference resistances to a minimum resistance (R2ₘᵢₙ) when the third trim code is equal to the second minimum trim code. The fourth positive gain of block 625 is determined using the minimum resistance of the variable resistors 264 and 268 in Equation (1), above. The method of FIGS. 6A and 6B proceeds to block 630.

At block 630, the controller circuitry 120 determines a difference in the positive gain per LSB of the third trim code (B) by dividing a difference between the third and the fourth positive gains by a range of the second trim code (R2_{range}). The controller circuitry 120 determines the difference in the positive gain per LSB of the third trim code of the variable resistors 264 and 268 by dividing the positive gains determined at the blocks 620 and 625 by a number of increments between the second maximum and second minimum trim codes. The determination of the block 630 is illustrated by Equation (7), below. The method of FIGS. 6A and 6B proceeds to block 635.

$$B = \frac{{Gain}_{p o s} ( R {2}_{max} ) - {Gain}_{p o s} ( R {2}_{min} )}{R {2}_{r a n g e}} , \qquad Equation ( 7 )$$

At block 635, the controller circuitry 120 determines a first reference gain at the first maximum trim code (Gain_{ref}(R3pₘₐₓ)) of the second variable resistor 260. The first reference gain of block 635 is determined using the maximum resistance of the second variable resistor 260 in Equation (3), above. The method of FIGS. 6A and 6B proceeds to block 640.

At block 640, the controller circuitry 120 determines a second reference gain at the first minimum trim code (Gain_{ref}(R3pₘᵢₙ)) of the second variable resistor 260. The second reference gain of block 640 is determined using the minimum resistance of the second variable resistor 260 in Equation (3), above. The method of FIGS. 6A and 6B proceeds to block 645.

At block 645, the controller circuitry 120 determines a difference in the reference gain per LSB of the second trim code (C) by dividing a difference between the first and the second reference gains by the range of the second trim code. The controller circuitry 120 determines the difference in the reference gain per LSB of the second trim code of the second variable resistor 260 by dividing the reference gains determined at the blocks 635 and 640 by the number of increments between the first maximum and first minimum trim codes. The determination of the block 645 is illustrated by Equation (8), below. The method of FIGS. 6A and 6B proceeds to block 650.

$$C = \frac{{Gain}_{ref} ( R 3 {p}_{max} ) - {Gain}_{ref} ( R 3 {p}_{min} )}{R 3 {p}_{r a n g e}} , \qquad Equation ( 8 )$$

At block 650, the controller circuitry 120 determines a third reference gain at a second maximum trim code (Gain_{ref}(R2ₘₐₓ)) of the variable resistors 264 and 268. The third reference gain of block 650 is determined using the maximum resistance of the variable resistors 264 and 268 in Equation (3), above. The method of FIGS. 6A and 6B proceeds to block 655.

At block 655, the controller circuitry 120 determines a fourth reference gain at a second minimum trim code (Gain_{ref}(R2 min)) of the variable resistors 264 and 268. The fourth reference gain of block 655 is determined using the minimum resistance of the variable resistors 264 and 268 in Equation (3), above. The method of FIGS. 6A and 6B proceeds to block 660.

At block 660, the controller circuitry 120 determines a difference in the reference gain per LSB of the third trim code (D) by dividing a difference between the third and the fourth reference gains by the range of the third trim code. The controller circuitry 120 determines the difference in the reference gain per LSB of the third trim code of the variable resistors 264 and 268 by dividing the reference gains determined at the blocks 650 and 655 by the number of increments between the second maximum and second minimum trim codes. The determination of the block 660 is illustrated by Equation (9), below. The method of FIGS. 6A and 6B proceeds to block 665

$$D = \frac{{Gain}_{ref} ( R {2}_{max} ) - {Gain}_{ref} ( R {2}_{min} )}{R {2}_{r a n g e}} , \qquad Equation ( 9 )$$

At block 665, the controller circuitry 120 determines a positive gain error (E) of a voltage output when an input voltage is positive. For example, the controller circuitry 120 uses Equation (1), above to determine a positive gain of the instrumentation amplifier 130 by measuring the voltage output 212 of FIG. 2 following the controller circuitry 120 turning on the transistor 140 of FIG. 1 and turning off the transistor 150 of FIG. 1. In such an example, the controller circuitry 120 calculates the positive gain error based on a comparison of a target positive gain and the positive gain determined using the voltage output 212. The target positive gain is an ideal positive gain of the instrumentation amplifier 130 when the voltage difference between the reference inputs 204 and 208 is positive and without errors. The target positive gain may be determined by a device designer, set during manufacturing, determined by processor circuitry, etc. The method of FIGS. 6A and 6B proceeds to block 670.

At block 670, the controller circuitry 120 determines a reference gain error (F) of a voltage output. For example, the controller circuitry 120 uses Equation (3), above to determine a reference gain of the instrumentation amplifier 130 by measuring the voltage output 212 and using the analog voltage of the DAC 330 of FIG. 3 as a voltage of the reference voltage input 216. In such an example, the controller circuitry 120 calculates the reference gain error by subtracting the determined reference gain from one. In the example of FIG. 2, an ideal reference gain is equal to one to enable the reference voltage input 216 to modify a DC offset of the voltage output 212 without affecting the positive gain of the instrumentation amplifier 130. The method of FIGS. 6A and 6B proceeds to block 675.

At block 675, the controller circuitry 120 determines the second trim code based on the positive gain error, the reference gain error, and the differences in the positive gain and the reference gain per LSB of the second trim code and the third trim code. The controller circuitry 120 determines a number of bits to change to the second trim code, referred to as a trim code adjustment, (Trimcode_{Δ}(R3ₚ)) by dividing a multiplication of the difference in the reference gain per LSB of the third trim code (D) and the positive gain error (E) minus a multiplication of the difference in the positive gain per LSB of the third trim code (B) and the reference gain error (F) by a subtraction of a multiplication of the difference in the positive gain per LSB of the third trim code (B) and the difference in the reference gain per LSB of the second trim code (C) from a multiplication of the difference in the positive gain per LSB of the second trim code (A) and the difference in the reference gain per LSB of the third trim code (D). The controller circuitry 120 may calculate the trim code adjustment of the second trim code using Equation (10), below.

$$Trim c {ode}_{Δ} ( {R}_{3 p} ) = \frac{( D * E ) - ( B * F )}{( A * D ) - ( B * C )} , \qquad Equation ( 10 )$$

The controller circuitry 120 determines the second trim code by adding the determined number of bits to change to the initial value that was set when determining the positive and reference gain errors. The method of FIGS. 6A and 6B proceeds to block 680.

At block 680, the controller circuitry 120 determines the third trim code based on the positive gain error, the reference gain error, and the differences in the positive gain and the reference gain per LSB of the second trim code and the third trim code. The controller circuitry 120 determines a number of bits to change to the third trim code (Trimcode_{Δ}(R₂)) by dividing a multiplication of the difference in the positive gain per LSB of the second trim code (A) and the reference gain error (F) minus a multiplication of the difference in the reference gain per LSB of the second trim code (C) and the positive gain error (E) by a subtraction of a multiplication of the difference in the positive gain per LSB of the third trim code (B) and the difference in the reference gain per LSB of the second trim code (C) from a multiplication of the difference in the positive gain per LSB of the second trim code (A) and the difference in the reference gain per LSB of the third trim code (D). The controller circuitry 120 may calculate the trim code adjustment of the third trim code using Equation (11), below.

$$Trim c {ode}_{Δ} ( {R}_{2} ) = \frac{( A * F ) - ( C * E )}{( A * D ) - ( B * C )} , \qquad Equation ( 11 )$$

The controller circuitry 120 determines the third trim code by adding the determined number of bits to change to the initial value that was used when measuring the positive and reference gain errors. The method of FIGS. 6A and 6B proceeds to return.

Although example methods are described with reference to the flowchart illustrated in FIGS. 6A and 6B, many other methods of determining the resistances of the variable resistors 260-268 to reduce positive gain error and reference gain error may alternatively be used in accordance with this description. For example, the order of execution of the blocks may be changed, and/or some of the blocks described may be changed, eliminated, or combined. Similarly, additional operations may be included in the manufacturing process before, in between, or after the blocks shown in the illustrated examples.

In this description, the term “and/or” (when used in a form such as A, B and/or C) refers to any combination or subset of A, B, C, such as: (a) A alone; (b) B alone; (c) C alone; (d) A with B; (e) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

The term “couple” is used throughout the specification. The term may cover connections, communications, or signal paths that enable a functional relationship consistent with this description. For example, if device A provides a signal to control device B to perform an action, in a first example device A is coupled to device B, or in a second example device A is coupled to device B through intervening component C if intervening component C does not substantially alter the functional relationship between device A and device B such that device B is controlled by device A via the control signal provided by device A.

Numerical identifiers such as “first”, “second”, “third”, etc. are used merely to distinguish between elements of substantially the same type in terms of structure and/or function. These identifiers as used in the detailed description do not necessarily align with those used in the claims.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors are described herein, other transistors (or equivalent devices) may be used instead with little or no change to the remaining circuitry. For example, a metal-oxide-silicon FET (“MOSFET”) (such as an n-channel MOSFET, nMOSFET, or a p-channel MOSFET, pMOSFET), a bipolar junction transistor (BJT—e.g., NPN or PNP), insulated gate bipolar transistors (IGBTs), and/or junction field effect transistor (JFET) may be used in place of or in conjunction with the devices disclosed herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a gallium nitride substrate (GaN) or a gallium arsenide substrate (GaAs).

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero.

Modifications are possible in the described embodiments, and other embodiments are possible, within the scope of the claims.

What is claimed is:

1. An apparatus comprising:
a first amplifier including a first inverting terminal, a first non-inverting terminal, a second non-inverting terminal, and a second inverting terminal, the first inverting terminal coupled to a first resistor, the first non-inverting terminal coupled to a second resistor;
a first transistor including a first control terminal, a first current terminal, and a second current terminal, the first control terminal coupled to the second non-inverting terminal, and the first current terminal coupled to the first inverting terminal;
a second transistor including a second control terminal, a third current terminal, and a fourth current terminal, the second control terminal coupled to the second inverting terminal, and the third current terminal coupled to the first non-inverting terminal;
a second amplifier including a third non-inverting terminal, a third inverting terminal, and a measurement terminal, the third non-inverting terminal configured to be coupled to the second current terminal, the third inverting input configured to be coupled to the fourth current terminal;
a first variable resistor coupled to the third non-inverting terminal;
a second variable resistor coupled between the third non-inverting terminal and a reference terminal;
a third variable resistor coupled to the third inverting terminal; and
a fourth variable resistor coupled between the third inverting terminal and the measurement terminal.

2. The apparatus of claim 1, further comprising controller circuitry coupled to the first variable resistor, the second variable resistor, the third variable resistor, and the fourth variable resistor, the controller circuitry including circuitry to set the first variable resistor to a first resistance, the second variable resistor to a second resistance, the third variable resistor to the first resistance, and the fourth variable resistor to a third resistance.

3. The apparatus of claim 2, wherein the controller circuitry includes circuitry to set the first resistance and the second resistance to correct for gain error when a positive voltage is supplied to the first amplifier by the first resistor and the second resistor.

4. The apparatus of claim 2, wherein the controller circuitry includes circuitry to set the third resistance to correct for gain error when a negative voltage is supplied to the first amplifier by the first resistor and the second resistor.

5. The apparatus of claim 1, wherein the first resistor includes a first resistance, the second resistor includes a second resistance, the first variable resistor includes a third resistance, and the third variable resistor includes a fourth resistance, the first resistance is equal to the second resistance, and the third resistance is equal to the fourth resistance.

6. The apparatus of claim 1, further including a third transistor including a fifth current terminal and a sixth current terminal, the fifth current terminal coupled to the second current terminal, the sixth current terminal coupled to the third non-inverting terminal.

7. The apparatus of claim 1, wherein the first amplifier is a fully differential amplifier and the second amplifier is a differential amplifier.

8. An instrumentation amplifier comprising:
a transconductance stage including:
a fully differential amplifier configured to generate a differential current based on a voltage input; and
a transistor configured to be controlled by an output of the fully differential amplifier and source current from an input of the fully differential amplifier; and
a transimpedance stage coupled to the transconductance stage, the transimpedance stage including:
resistor circuitry configured to convert the differential current into a differential voltage using a first resistance, a second resistance, and a third resistance; and
a differential amplifier configured to convert the differential voltage to a single-ended voltage, the single-ended voltage represents the voltage input.

9. The instrumentation amplifier of claim 8, wherein the transistor is a first transistor, the input is a first input, and the output is a first output, the transconductance stage further including a second transistor configured to be controlled by a second output of the fully differential amplifier, and source current from a second input of the fully differential amplifier.

10. The instrumentation amplifier of claim 8, wherein the transconductance stage further includes a first resistor and a second resistor that couple the voltage input to the fully differential amplifier.

11. The instrumentation amplifier of claim 8, wherein the resistor circuitry includes a first resistor, a second resistor, a third resistor, and a fourth resistor, the first resistor including the first resistance, the second resistor including the second resistance, the third resistor including the third resistance, and the fourth resistor including the second resistance.

12. The instrumentation amplifier of claim 8, further comprising controller circuitry configured to determine the first resistance, the second resistance, and the third resistance based on a first gain when the voltage input is negative and a second gain when the voltage input is positive.

13. The instrumentation amplifier of claim 8, wherein the first resistance, the second resistance, and the third resistance are variable resistances configured to reduce gain error.

14. The instrumentation amplifier of claim 8, wherein the first resistance, the second resistance, and the third resistance are variable resistances configured to reduce offset error.

15. A method comprising:
supplying a negative voltage to an input of an instrumentation amplifier;
determining, by controller circuitry, a negative gain based on the negative voltage and an output of the instrumentation amplifier in response to the negative voltage;
determining, by controller circuitry, a modified first trim code based on the negative gain and a first trim code;
setting, by the controller circuitry, a first variable resistor to a first resistance based on the modified first trim code;
supplying a positive voltage to the input of the instrumentation amplifier;
determining, by the controller circuitry, a positive gain based on the positive voltage and the output of the instrumentation amplifier in response to the positive voltage;
determining, by the controller circuitry, a reference gain based on a reference voltage and the output of the instrumentation amplifier in response to the positive voltage;
determining, by the controller circuitry, a modified second trim code based on the positive gain, the reference gain, and a second trim code;
setting, by the controller circuitry, a second variable resistor to a second resistance based on the modified second trim code;
determining, by the controller circuitry, a modified third trim code based on the positive gain, the reference gain, and a third trim code; and
setting, by the controller circuitry, a third variable resistor to a third resistance based on the modified third trim code.

16. The method of claim 15, further including determining a change in the negative gain per least significant bit (LSB) of the first trim code.

17. The method of claim 16, further including adding a trim code adjustment to the first trim code to generate the modified first trim code, the trim code adjustment equal to a negative gain error divided by the change in the negative gain per LSB of the first trim code.

18. The method of claim 15, further including:
determining a change in the positive gain per LSB of the second trim code;
determining a change in the reference gain per LSB of the second trim code;
determining a change in the positive gain per LSB of the third trim code; and
determining a change in the reference gain per LSB of the third trim code.

19. The method of claim 18, further including adding a trim code adjustment to the second trim code to generate the modified second trim code, the trim code adjustment based on the change in the positive gain per LSB of the third trim code, a reference gain error, the change in the reference gain per LSB of the third trim code, a positive gain error, the change in the positive gain per LSB of the third trim code, the change in the reference gain per LSB of the second trim code, and the change in the positive gain per LSB of the second trim code.

20. The method of claim 18, further including adding a trim code adjustment to the third trim code to generate the modified third trim code, the trim code adjustment based on the change in the reference gain per LSB of the second trim code, a positive gain error, the change in the positive gain per LSB of the second trim code, a reference gain error, the change in the positive gain per LSB of the third trim code, and the change in the reference gain per LSB of the third trim code.
